(19) United States
(12) Patent Application Publication
(10) Pub. No.: US 2002/0197784 A1
(43) Pub. Date: Dec. 26, 2002

(54) Method for forming a gate dielectric layer by a single wafer process

(76) Inventors: Tuung Luoh, Kaohsiung City (TW); Chin-Hsiang Lin, Nan-Tao (TW); Yaw-Lin Hwang, Taipei City (TW)

Correspondence Address: LOWE HAUPTMAN GILMAN & BERNER, LLP, Suite 300, 1700 Diagonal Road, Alexandria, VA, 22314, US

(21) Appl. No.: 10/212,224

(22) Filed: Aug. 6, 2002

Related U.S. Application Data
(63) Continuation-in-part of application No. 09/861,655, filed on May 22, 2001.

(51) Int. Cl. H01L 21/8238

(52) U.S. Cl. 438/211

(57) ABSTRACT

A method for forming a gate dielectric layer by a single wafer process is provided. The method for forming a gate dielectric layer by a single wafer process is accomplished by two steps respectively performed in a single-wafer chamber and a single-wafer rapid thermal processing (RTP) chamber. First, by placing a silicon wafer in the single-wafer chamber and performing an oxynitridation process to form a nitrogen-contained silicon oxide layer on the surface of the silicon wafer. Then, placing the silicon wafer in the single-wafer RTP chamber and performing an in-situ steam generation (ISSG) rapid thermal oxidation process to oxidize the nitrogen-contained silicon oxide layer to a composite layer formed of an upper silicon oxynitride layer and a lower silicon oxide layer serving for a gate dielectric layer.

The present application is a continuation-in-part of prior U.S. patent application Ser. No. 09/861,655, filed May 22, 2001.

### BACKGROUND OF THE INVENTION

1. Field of the Invention

The present invention relates to a method for forming a gate dielectric layer for a narrow channel length MOSFET (metal-oxide-semiconductor field effect transistor) device; and more particularly to a method for forming a gate dielectric layer by a single wafer process.

2. Description of the Prior Art

The trend in integrated circuits is leaning toward higher performance, higher speed, and lower cost. Correspondingly, device dimensions and feature sizes are shrinking for all types of integrated circuit technology. The trend necessitates the use of ultra-thin dielectrics in the fabrication of such devices as metal-oxidesemiconductor (MOS) transistors.

MOS transistors are comprised of highly doped source and drain regions in a silicon substrate, and a conducting gate electrode is situated between the source and drain but separated from the substrate by a thin gate dielectric layer. When an appropriate voltage is applied to the gate electrode, a conducting channel is created between the source and drain. Shorter channels, shallower source and drain junctions, and thinner gate dielectrics are critical to achieve smaller and faster MOS devices.

Ultra-thin dielectrics less than 100 angstroms thick, to less than 15 angstroms for the 0.1 urn generation is usually of high quality SiO₂, and utilized as MOS gate dielectrics, commonly called gate oxides. While for the same gate oxide material, several quantum effects, such as boron penetration and the hot carrier effect may occur when the thickness of the gate oxide is shrunk from several hundred angstroms to several tens angstroms. With ultra-thin gate oxide, boron from the doped polysilicon gate can diffuse completely through the gate oxide into the underlying substrate, causing even more severe of a threshold shift problem. The hot electrons generated near the drain region, are easily injected into the ultra-thin gate oxide due to the hot carrier effect, resulting in damage to the gate oxide and/or the Si-SiO₂ interface. Furthermore, reliability and reproducibility of the ultra-thin gate oxide is adversely affected by these factors including poor interface structure, high defect density, lacking of thickness control and impurity diffusion through the gate oxide. Theses factors also can seriously degrade device performance.

Incorporation of nitrogen into the ultra-thin gate oxide has been shown to inhibit boron penetration and to improve the Si-SiO₂ interfacial structure. Ultra-thin oxide (12˜20 angstroms) quality control and the method to incorporate nitrogen are the keys to enable the scaling oxide application extended to 0.1 urn generation. Conventionally, nitrogen incorporation in a top portion of a silicon substrate is implemented by way of nitrogen implantation. However, the nitrogen implantation easily damages the structure of the silicon substrate being implanted, and then causing the pin hole issue during the subsequent gate oxide growth. It is also difficult to control the nitrogen profile in the top portion of the silicon substrate when the nitrogen incorporation is implemented by the nitrogen implantation. In the end, it's hard to obtain an ultra-thin gate dielectric layer with a uniform thickness.

However, for the conventional furnace-based oxidation, as described in “Fundamental of Semiconductor Processing Technology” pp. 54-58 by Badih El-Kaveh, IBM corporation, a batch of wafers is introduced into the furnace in a slow traveling boat and heated to the oxidation temperature. The wafers are held at this elevated temperature for a specific time and then brought back to a low temperature. The typical temperature transition rate is about 0.1° C./s for furnace processing. For example, it takes about 35 minutes for ramp-up to the oxidation temperature about 1000° C. , and maintaining at this temperature about 50 minutes. Then, it takes about 35 minutes for ramp-down to the low temperature. There are three kinds of conventional furnace oxidation, dry oxidation, wet oxidation and steam oxidation. For dry oxidation, oxygen mixed with an inert carrier gas such as nitrogen, is passed over the wafers at the elevated temperature. Wet oxidation is performed by bubbling oxygen through a high purity water bath maintained between 85° C. and 95° C. The temperature of the batch determines the partial pressure of water in the oxygen gas stream. The mixture is passed over the wafer at the elevated temperature. In pyrogenic steam oxidation, the oxidizing medium is water vapor formed by a direct reaction of hydrogen with oxygen. Van Zant, VLSI Farbication, 4^{th} ed, McGraw-Hill: New York, 2000, pp.172-173, also describes a pyrogenic steam oxidation in furnace, of which oxygen gas and hydrogen gas are directly introduced into a furnace tube. Inside the furnace tube, oxygen gas and hydrogen gas mix and, under the influence of the high temperature, form steam. The resulting steam then reacts with silicon surface of the wafer to grow a silicon dioxide layer on the wafer. The mechanism of steam oxidation for the silicon wafer in a furnace tube is set forth in the following:

2H₂O+O₂→2H₂O

Si+2H₂O→SiO₂+2H₂

For the conventional furnace-based oxidation, a batch of silicon wafers is simultaneously oxidized to form a gate oxide layer on each of the silicon wafers in the furnace. The thickness uniformity of the gate oxide layers for the silicon wafers formed by the conventional furnace-based oxidation can not be controlled properly. Furthermore, the conventional furnace-based oxidation is difficult to scale below 20 angstroms, and the lower temperatures used during oxidation degrade oxide quality. Therefore, the conventional furnace-based oxidation can not provide an ultra-thin gate oxide with good quality. In addition, one limitation of furnace oxidation is its inertia to temperature transition, which results in a higher thermal budget than required for oxidation.

Accordingly, it is an intention to provide a method for forming a gate dielectric layer, especially for a narrow channel length MOSFET device, by a single-wafer process, which can overcome the drawbacks of the conventional methods.

### SUMMARY OF THE INVENTION

It is an objective of the present invention to provide a method for forming a gate dielectric layer by a single wafer process, that is accomplished by two steps of an oxynitridation process in a single-wafer chamber and an in-situ steam generation (ISSG) rapid thermal oxidation process in a single-wafer RTP chamber. The single-wafer chamber and single-wafer rapid thermal processing chamber can be integrated in a unit, so that the oxynitridation process and in-situ steam generation rapid thermal oxidation process can be integrated in a single-wafer thermal process, thereby improving the throughput.

It is another objective of the present invention to provide a method for forming a gate dielectric layer by a single wafer process, in which a silicon wafer is placed in a single-wafer chamber and annealed in a nitric oxide (NO)/or nitrous oxide (N₂O) ambient. As a result, a nitrogen-contained silicon oxide layer with a uniform nitrogen profile is formed on the silicon wafer. The damage of the silicon wafer for nitrogen incorporation by the conventional nitrogen implantation is avoided.

It is a further objective of the present invention to provide a method for forming a gate dielectric layer by a single wafer process, in which an in-situ steam generation (ISSG) rapid thermal oxidation process is performed to oxidize a nitrogen-contained silicon oxide layer on a silicon wafer to a composite layer formed of an upper silicon oxynitride layer and a lower silicon oxide layer. The composite layer formed by the ISSG rapid thermal oxidation process provides an excellent controlled thickness and is suitably used as an ultra-thin gate dielectric layer.

In order to achieve the above objectives, the present invention provides a method for forming a gate dielectric layer by a single wafer process. A single silicon wafer with a first conductive type is provided. A plurality of isolation regions are formed in the silicon wafer and a well region with a second conductive type opposite to the first conductive type is formed in a top portion of the silicon wafer between a pair of the isolation regions. The silicon wafer is placed in a single-wafer chamber to perform an oxynitridation process to form a nitrogen-contained silicon oxide layer on the surface of the well region. Then, the silicon wafer is placed in a single-wafer rapid thermal processing chamber to perform an in-situ steam generation (ISSG) rapid thermal oxidation process to oxidize the nitrogen-contained silicon oxide layer to a composite layer formed of an upper silicon oxynitride layer and a lower silicon oxide layer serving for a gate dielectric layer.

### BRIEF DESCRIPTION OF THE DRAWINGS

The foregoing and other advantages and features of the invention will be apparent from the following more particular description of the preferred embodiments of the invention, as illustrated in the accompanying drawings.

FIG. 1A to FIG. 1C shows schematic cross-sectional views of various steps of one embodiment of the present invention; and

FIG. 2 is a process flow showing various steps of the embodiment of FIG. 1.

### DESCRIPTION OF THE PREFERRED EMBODIMENTS

The present method for forming a gate dielectric layer by a single wafer process, that is especially applicable in an ultra-thin gate dielectric layer, will be described in detail. The ultra-thin gate dielectric layer, obtained by the present method, can be applied to both a P channel MOS device and an N channel MOS device.

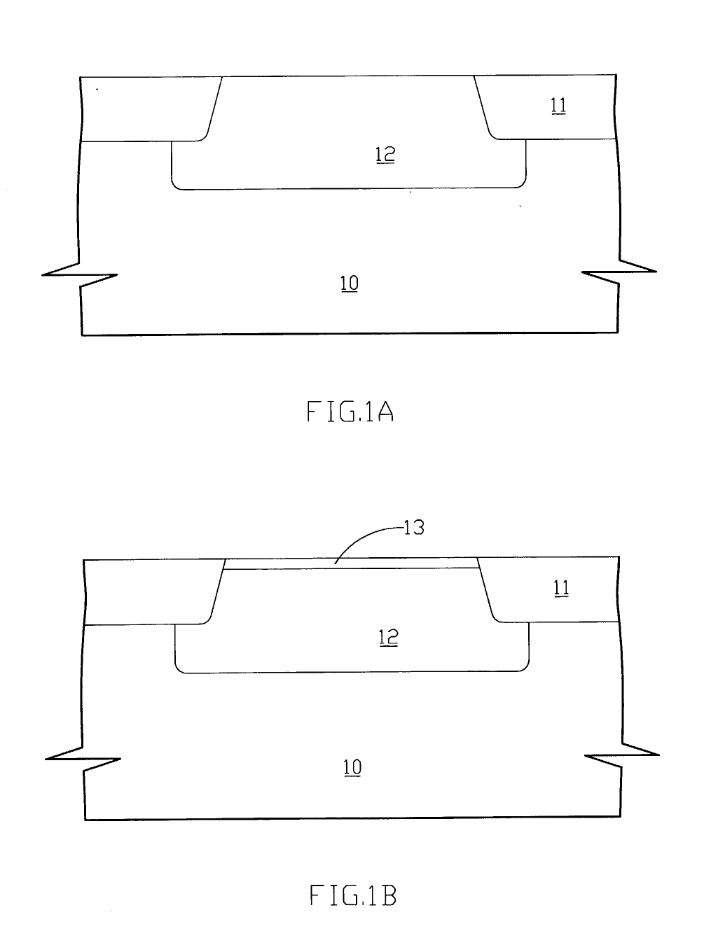

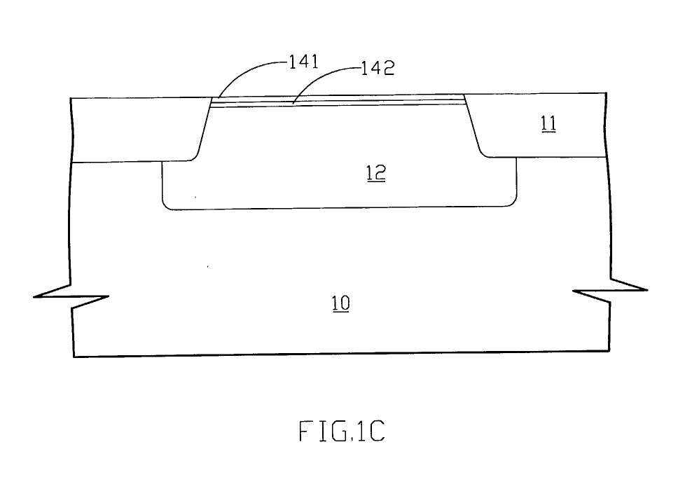

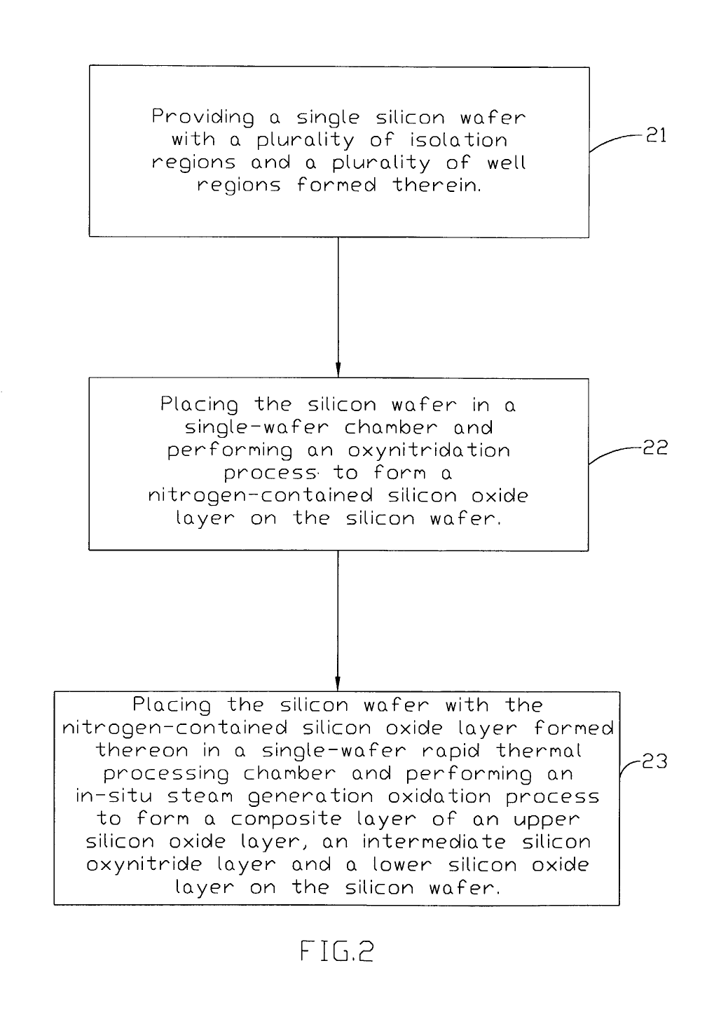

A single silicon wafer 10, comprised of P type single crystalline silicon, with a <100> crystallographic orientation, is used and schematically shown in FIG. 1A. A plurality of isolation regions, comprised of silicon dioxide, defined as either a shallow trench isolation (STI) region or field oxide region, are formed in the silicon wafer 10. The shallow trench isolations are created via initially forming a plurality of shallow trenches in the silicon wafer 10 by the conventional photolithographic and reactive ion etching method, followed by filling the shallow trenches with silicon dioxide, via a low pressure chemical vapor deposition (LPCVD) method, or a plasma enhanced chemical vapor deposition (PECVD) method. A chemical mechanical polishing process is then employed to remove portions of the silicon dioxide above the top surface of the silicon wafer 10, resulting in the desired shallow trench isolations. The field oxide regions are obtained via thermal oxidation of exposed regions of the silicon wafer 10 not protected by an oxidation resistant mask pattern, such as silicon nitride. After formation of the field oxide regions, the oxidation resistant mask pattern is removed. When the ultra-thin gate dielectric layer is applied to a P channel MOS device, an N well region 12 is next formed in a top portion of the silicon wafer 10 between a pair of isolation regions 11, via the conventional photolithographic and. ion implantation processes. After forming a photoresist on the silicon wafer 10, an ion implantation process is performed. Phosphorous or arsenic ions are used, at energy between about 40 to 80 Kev, with a dose between about 4×10¹⁵ to 8×10¹⁵ ions/cm², to form the N well region 12. The photoresist, used as a mask for definition of the N well region 12, is removed via plasma oxygen ashing and careful wet cleaning. When the ultra-thin gate dielectric layer is applied to an N channel MOS device, the well region would be a P well region, formed using boron or BF₂ as implanted ions.

In accordance with the process flow of FIG. 2, the method for forming a gate dielectric layer by a single wafer process in a narrow channel length MOSFET device, (e.g. below 0.25 um for the channel length), will be described. The present method for forming an ultra-thin gate dielectric layer is accomplished by two steps of an oxynitridation process in a single-wafer chamber and then an in-situ steam generation rapid thermal oxidation process in a single-wafer rapid thermal processing (RTP) chamber. A pre-clean process, using a dilute hydrofluoric acid solution, is used prior to the initiation of the process flow of FIG. 2. With reference to FIG. 2, in step 21, the silicon wafer 10 with isolation regions 11 and well regions, such as N well regions 12, formed therein, as shown in FIG. 1A, is provided. Then, in step 22, the silicon wafer 10 is placed in a single-wafer chamber containing a nitric oxide (NO) ambient/or a nitrous oxide (N₂O) ambient. An oxynitridation process is implemented on the silicon wafer 10 by way of annealing the silicon wafer 10 at a temperature of about 700˜1200° C. in the nitric oxide ambient/or nitrous oxide ambient, forming a nitrogen-contained silicon oxide layer 13 on the surface of the N well region 12, for example, as shown in FIG. 1B. Followed by step 23, the silicon wafer 10 is then placed in a single-wafer rapid thermal processing (RTP) chamber. During the rapid thermal processing chamber, the wafer is rapidly heated from a low temperature to a high temperature. The wafer is held at this elevated temperature for a short time and then brought back rapidly to the low temperature. Typical temperature transition rates range from 10° C./s to 350° C./s. The rapid thermal process duration at the high processing temperature vary from 1 second to 5 minutes. An in-situ steam generation (ISSG) rapid thermal oxidation process is performed to oxidize the nitrogen-contained silicon oxide layer 13 on the silicon wafer 10 to form a composite layer formed of an upper silicon oxynitride layer 141 and a lower silicon oxide layer 142, as shown in FIG. 1C. The composite layer formed of an upper silicon oxynitride layer 141 and a lower silicon oxide layer 142 can be used as a gate dielectric layer for a narrow channel length MOSFET device.

The in-situ steam generation rapid thermal oxidation process can be performed by way of introducing pre-mixed H₂ and O₂ into the single-wafer rapid thermal processing chamber at a low pressure typically below 20 torr directly, without pre-combustion. The pre-mixed process gases (pure H₂ and O₂) flow across the silicon wafer 10 heated to a predetermined temperature. The wafer temperature initiates H₂ and O₂ converting to H₂O by the reaction (I) described below:

H₂+O₂→H₂O+O*+OH*+other species (I)

Atomic oxygen (O radicals) and hydroxyl radicals (OH radicals) are produced at the surface of the nitrogen-contained silicon oxide layer 13 of the silicon wafer 10. The atomic oxygen species cause efficient and controlled oxidation occurred on the nitrogen-contained silicon oxide layer 13 to form the composite layer formed of an upper silicon oxynitride layer 141 and a lower silicon oxide layer 142. The oxidation growth rate of the ISSG rapid thermal oxidation process exhibits a strong correlation to the atomic oxygen concentration and not to any other atomic or molecular species. The atomic oxygen concentration is also independent of the reactor volume and depends solely on pressure, temperature, and relative amount of hydrogen present in the chamber. Therefore, the thickness of the oxide layer can be controlled properly by the ISSG rapid thermal oxidation process, by way of controlling the reaction parameters such as temperature, pressure, flow rate, and hydrogen concentration. All of which can be controlled precisely by modern equipment to obtain an ultra-thin dielectric layer with excellent thickness uniformity and thickness control. For the present invention, the in-situ steam generation rapid thermal oxidation process is performed at a temperature of about 800 to 1300° C. in steam ambient, thereby forming a composite layer formed of an upper silicon oxynitride layer 141 and a lower silicon oxide layer 142 with a thickness about 10 to 100 angstroms on the silicon wafer 10, as shown in FIG. 1C.

In view of the foregoing, the present invention provides the following advantages:

1. The single-wafer chamber and single-wafer rapid thermal processing chamber can be integrated in a unit, so that the oxynitridation process and the in-situ steam generation rapid thermal oxidation process can be easily integrated in a single-wafer thermal process, and thereby improving the throughput.

2. The present invention provides a uniform nitrogen profile for nitrogen incorporation and prevents the silicon wafer from being damaged. The pinhole issue during the subsequent oxidation is therefore avoided.

3. The present invention provides a gate dielectric layer with excellent thickness control and excellent thickness uniformity that is suitable for formation of an ultra-thin gate dielectric layer.

The preferred embodiments are only used to illustrate the present invention, it is not intended to limit the scope thereof. Many modifications of the preferred embodiments can be made without departing from the spirit of the present invention.

What is claimed is:

1. A method for forming a gate dielectric layer by a single wafer process, comprising:
providing a single silicon wafer with a first conductive type;
forming a plurality of isolation regions in said silicon wafer;
forming a well region with a second conductive type opposite to said first conductive type in a top portion of said silicon wafer between a pair of said isolation regions;
placing said silicon wafer in a single-wafer chamber to perform an oxynitridation process to form a nitrogen-contained silicon oxide layer on the surface of said well region; and
placing said silicon wafer in a single-wafer rapid thermal processing chamber to perform an in-situ steam generation (ISSG) rapid thermal oxidation process to oxidize said nitrogen-contained silicon oxide layer to a composite layer formed of an upper silicon oxynitride layer and a lower silicon oxide layer serving for a gate dielectric layer.

2. The method of claim 1, wherein said first conductive type is either of N type conductivity and P type conductivity.

3. The method of claim 1, wherein said oxynitridation process is performed at a temperature of about 700˜1200° C. in a nitric oxide (NO) ambient.

4. The method of claim 1, wherein said oxynitridation process is performed at a temperature of about 700˜1200° C. in a nitrous oxide (N₂O) ambient.

5. The method of claim 1, wherein said in-situ steam generation (ISSG) rapid thermal oxidation process is performed at a temperature between about 800 to 1300° C. in a steam ambient.

6. The method of claim 3, wherein said in-situ steam generation (ISSG) rapid thermal oxidation process is performed at a temperature between about 800 to 1300° C. in a steam ambient.

7. The method of claim 4, wherein said in-situ steam generation (ISSG) rapid thermal oxidation process is performed at a temperature between about 800 to 1300° C. in a steam ambient.

8. The method of claim 5, wherein said gate dielectric layer is formed with a thickness about 10˜100 angstroms.

9. The method of claim 6, wherein said gate dielectric layer is formed with a thickness about 10˜100 angstroms.

10. The method of claim 7, wherein said gate dielectric layer is formed with a thickness about 10˜100 angstroms.

11. A method for forming a gate dielectric layer by a single wafer process, comprising:
providing a single silicon wafer with a first conductive type;
forming a plurality of isolation regions in said silicon wafer;
forming a well region with a second conductive type opposite to said first conductive type in a top portion of said silicon wafer between a pair of said isolation regions;
placing said silicon wafer in a single-wafer chamber installed in a unit to perform an oxynitridation process to form a nitrogen-contained silicon oxide layer on the surface of said well region; and
placing said silicon wafer in a single-wafer rapid thermal processing chamber installed in said unit to perform an in-situ steam generation (ISSG) rapid thermal oxidation process to oxidize said nitrogen-contained silicon oxide layer to a composite layer formed of an upper silicon oxynitride layer and a lower silicon oxide layer serving for a gate dielectric layer.

12. The method of claim 11, wherein said first conductive type is either of N type conductivity and P type conductivity.

13. The method of claim 11, wherein said oxynitridation process is performed at a temperature of about 700˜1200° C. in a nitric oxide (NO) ambient.

14. The method of claim 11, wherein said oxynitridation process is performed at a temperature of about 700˜1200° C. in a nitrous oxide (N₂O) ambient.

15. The method of claim 11, wherein said in-situ steam generation (ISSG) rapid thermal oxidation process is performed at a temperature between about 800 to 1300° C. in a steam ambient.

16. The method of claim 13, wherein said in-situ steam generation (ISSG) rapid thermal oxidation process is performed at a temperature between about 800 to 1300° C. in a steam ambient.

17. The method of claim 14, wherein said in-situ steam generation (ISSG) rapid thermal oxidation process is performed at a temperature between about 800 to 1300° C. in a steam ambient.

18. The method of claim 15, wherein said gate dielectric layer is formed with a thickness about 10˜100 angstroms.

19. The method of claim 16, wherein said gate dielectric layer is formed with a thickness about 10˜100 angstroms.

20. The method of claim 17, wherein said gate dielectric layer is formed with a thickness about 10˜100 angstroms.
